(19) United States
(12) Patent Application Publication
(10) Pub. No.: US 2025/0265490 A1
(43) Pub. Date: Aug. 21, 2025

(54) VEHICLE BATTERY MANUFACTURING PROCESS

(71) Applicant: FORD GLOBAL TECHNOLOGIES, LLC, Dearborn, MI (US)

(72) Inventors: Elham HONARVARFARD, West Bloomfield, MI (US); Ann Marie STRACCIA, Southgate, MI (US); Gayatri BEERA, South Lyon, MI (US); Benjamin Eli SWERDLOW, Ann Arbor, MI (US); Vasko ILIEV, West Bloomfield, MI (US); Paul John BOJANOWSKI, Macomb Township, MI (US); Yu CHEN, Novi, MI (US)

(21) Appl. No.: 18/442,826

(22) Filed: Feb. 15, 2024

(51) Int. Cl. G06N 20/00; H01M 4/04; H01M 10/04; H01M 50/30

(52) U.S. Cl. CPC G06N 20/00; H01M 4/0447; H01M 10/0404; H01M 50/30; H01M 2220/20

(57) ABSTRACT

A trained model, implemented on a processor of a manufacturing line that produces battery cells, causes removal of certain of the battery cells from the manufacturing line responsive to the trained model identifying the certain of the battery cells as being subject to a predefined condition based on measured data from the certain of the battery cells on the manufacturing line provided to the trained model.

### TECHNICAL FIELD

The present disclosure generally relates to a vehicle battery manufacturing system. More specifically, the present disclosure relates to a system for detecting various battery conditions during manufacturing.

### BACKGROUND

Electric vehicles rely on a traction battery for supplying electric energy for propulsion. A traction battery usually includes a plurality of lithium-ion battery cells for storing electric energy.

### SUMMARY

A method includes training a model implemented on a processor on formation cycling gas analyzer data of training battery cells, formation cycling infrared thermal imaging data of the training battery cells, and current leakage data of the training battery cells to generate a trained model such that the trained model during deployment with a line configured to manufacture production battery cells causes removal of certain of the production battery cells from the line responsive to measurements associated with the production battery cells on the line being identified by the trained model as corresponding to a predefined condition.

A battery manufacturing system includes a trained model implemented on a processor of a manufacturing line that produces battery cells, and configured to cause removal of certain of the battery cells from the manufacturing line responsive to the trained model identifying the certain of the battery cells as being subject to a predefined condition based on measured data from the certain of the battery cells on the manufacturing line provided to the trained model.

A battery manufacturing system includes a model implemented on a processor of a manufacturing line that produces production battery cells, and trained on formation cycling gas analyzer data of training battery cells so as to be configured to cause removal of certain of the production battery cells from the manufacturing line responsive to the model identifying the certain of the production battery cells as being subject to an impending venting of gases based on gas data measured during a formation cycling stage of the certain of the production battery cells.

### BRIEF DESCRIPTION OF THE DRAWINGS

FIG. 1 illustrates a schematic diagram a lithium-ion battery manufacturing system of one embodiment of the present disclosure.

FIG. 2 illustrates a flow diagram of a process for identifying battery cells experiencing certain conditions of one embodiment of the present disclosure.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The present disclosure proposes, among other things, systems and methods for manufacturing rechargeable batteries. More specifically, the present disclosure proposes systems and methods for detecting lithium-ion battery cells experiencing certain conditions during the manufacturing process.

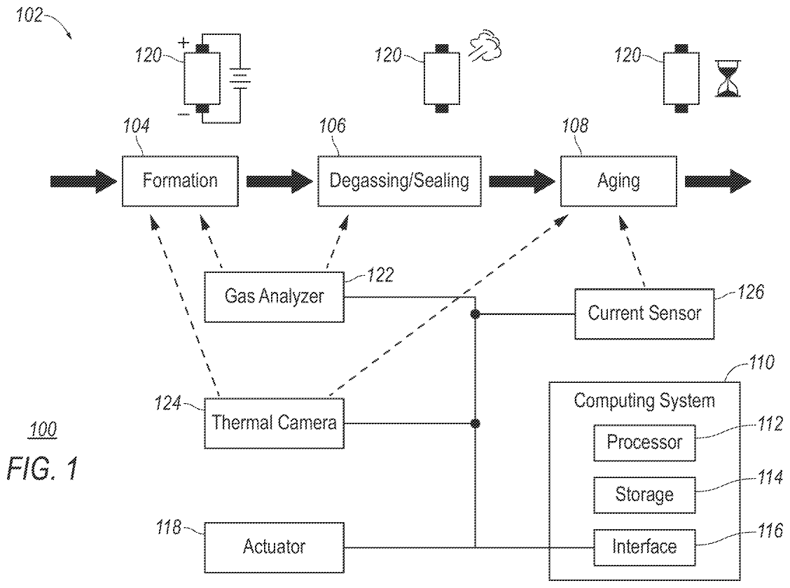

Referring to FIG. 1, an example schematic diagram of a lithium-ion battery manufacturing system 100 of one embodiment of the present disclosure is illustrated. A lithium-ion battery cell manufacturing process 102 may involve a variety of stages. For instance, the process may start with a mixing and coating stage to process the raw material and finish with the formation and aging stage to form the cells. The system of the present disclosure may be applied to one or more later stages of the manufacturing process 102 on or after the battery cells have been formed. More specifically, the system of the present disclosure may be applied to a formation stage 104, a degassing and sealing stage 106, and an aging stage 108 of the manufacturing process 102.

The battery manufacturing system 100 may include a computing system 110 configured to perform various operations. For instance, the computing system 110 may be provided with one or more processors 112 configured to perform instructions, commands, and other routines in support of the processes described herein. For instance, the computing system 110 may be configured to execute instructions of software applications to perform operations such as data processing and analysis, machine learning, and artificial intelligence algorithms. Such software applications and other data may be maintained in a non-volatile manner using a variety of types of computer-readable storage medium 114. The computer-readable medium 114 (also referred to as a processor-readable medium or storage) includes any non-transitory medium (e.g., tangible medium) that participates in providing instructions and other data that may be accessed by the processor 112 of the computing system 110. Computer-executable instructions may be compiled or interpreted from computer programs created using a variety of programming languages and/or technologies, including, without limitation, and either alone or in combination, Java, C, C++, C#, Objective C, Fortran, Pascal, Java Script, Python, Perl, and structured query language (SQL).

The computing system 110 may be provided with one or more interfaces 116 configured to communicate and interact with various onboard and/or off-board devices configured to provide various functions. For instance, the computing system 110 may drive or otherwise communicate with an actuator 118 configured to perform operational maneuvers to one or more battery cells 120 via the interface 116. The actuator 118 may include one or more machinery arms (not shown) or electric motors (not shown) to facilitate placing and/or removing one or more of the battery cells 120 from the manufacturing process 102 as monitored and directed by the computing system 110. The interface 116 may be fully or partially implemented via various wired data communication protocols and/or networks. For instance, the interface 116 may be implemented via one or more of an Ethernet network, universal serial bus (USB) protocol, or the like. Additionally or alternatively, the interface 116 may be fully or alternatively further implemented via one or more wireless communication networks such as Wi-Fi, Bluetooth, cellular network, or the like.

The computing system 110 may further drive or otherwise communicate with one or more gas analyzers 122 configured to detect gas emitted from the battery cells 120 during the manufacturing process 102 via the interface 116. More specifically, the gas analyzer 122 may be configured to identify a concentration of one or more target elements/chemistries emitted in the gas form from the cells 120 during the formation stage 104 and the degassing and sealing stage 106 to identify a possible battery cell condition. In the present example, the positive and negative terminals of the cells 120 are connected to a power source to receive electric charge for the first time and be cycled between charge and discharge cycles to stabilize and activate the battery chemistry during the cell formation stage 104 of the manufacturing process 102. Internal gas may be generated and emitted when electric charging is supplied to the battery cells 120 the first time increasing the internal pressure. In some cases, the internal gas may cause the battery cell pouches to inflate/bulge which may be a normal phenomenon before the pouches are sealed.

After the formation stage 104, the cells 120 will be transported to the degassing and sealing stage 106 in which the gas may be further released. Depending on the specific chemical compositions and physical configurations of the battery cells 120 being manufactured, some of the cells 120 may be associated with one or more predetermined chemical characteristics in the gas emitted. For instance, gas chemistries such as C₂H₄, CO₂, CO, O₂, H₂, CH₄, and C₂H₆ may be emitted and measured by the gas analyzer 122. The computing system 110 may use the concentration of the one of more gasses measured by the gas analyzer 122 to determine one or more cells and have the cells removed using the actuator 118. (To be discussed in detail below).

The computing system 110 may further drive or otherwise communicate with one or more thermal cameras 124 configured to monitor the temperature of the battery cells 120 via the interface 116. The thermal camera 124 may include an infrared sensor to capture infrared radiation emitted from the battery cells 120 to determine a temperature of the cells. The temperature measured by the thermal camera 124 may be an external temperature outside the body/pouch of the battery cells 120. However, due to the nature of heat conduction, a higher external temperature may be used to infer a higher internal battery cell temperature. The temperature measurement may be performed during the formation stage 104 of the manufacturing process 102. Additionally or alternatively, the temperature measurement via the thermal camera 124 may be performed during the aging stage 108 after the battery cells 120 have been degassed and sealed at stage 106. During the aging process, the battery cells 120 may be placed at room temperature or high temperature for a predefined duration of time to make the battery properties and chemical composition more stable. Heat may be generated during both the formation stage 104 and the aging stage 108. Depending on the specific property and physical configurations of the battery cells 120, some of the battery cells 120 may generate and emit more heat compared with normal cells 120. Therefore, the increased heat may increase both the internal and external temperature of some of the cells 120. The thermal camera 124 may be used to identify one or more cells 120 with higher measured temperature compared with other cells. The computing system 110 may cause the removal of some of the cells using the actuator 118.

The computing system 110 may further drive or otherwise communicate with one or more current sensors 126 configured to measure a potentiostatic discharge current of one or more battery cells 120 via the interface 116. As discussed above, the battery cells 120 are charged with electric energy at the formation stage 104. During the aging stage 108, the battery cells 120 are placed in a facility with control conditions (e.g., temperature) for a predefined period. It is normal that a small potentiostatic current is generated during the aging period. The current sensor 126 may be connected to the positive and negative terminals of the battery cells 120 to measure the discharge current. If the potentiostatic discharge current is greater than a predefined threshold, the computing system 110 may identify a possible issue and have the corresponding cell 120 removed using the actuator.

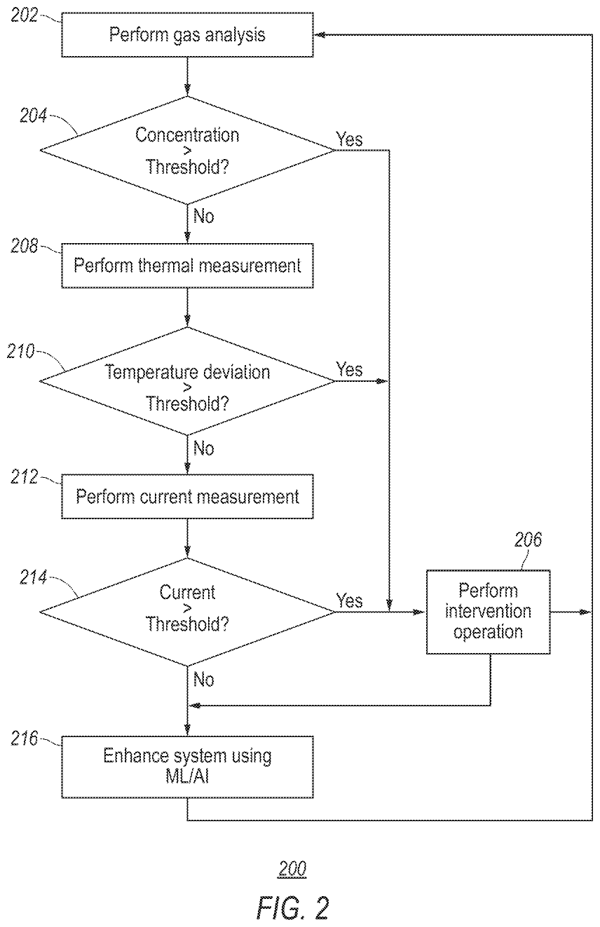

Referring to FIG. 2, an example flow diagram of a process 200 for manufacturing battery cells and detecting cell conditions is illustrated. With continuing reference to FIG. 1, the process 200 may be implemented via one or more components of the battery manufacturing system 100.

The operations of the process 200 may be performed at different stages of the manufacturing process 102. For instance, the operation 202 may be implemented at the cell formation stage 104 and the degassing and sealing stage 106 to perform a gas analysis using the gas analyzer 122. As discussed above, the gas analyzer 122 may be configured to measure the concentration of the various related gas chemistries such as C₂H₂, CO₂, CO, O₂, H₂, CH₄ and C₂H₆. The concentration of different gas chemistry may reflect the states and conditions of the battery cells 120. A baseline gas profile may be available for each targeted chemistry at each relevant stage of the manufacturing process 102. The gas emitted from the battery cells 120 at each stage may be measured and evaluated by the gas analyzer 122. The concentration of each gas chemistry of interest may be compared with one or more thresholds indicated in the corresponding baseline gas profile by the computing system 110. There may be multiple ways to perform the comparison. A percentage deviation method may be utilized to detect possible cells of interest. The percentage deviation may utilize different thresholds for the variety of gas chemistries. For example, a +/−1% deviation threshold may be used on a first gas chemistry (e.g., C₂H₂) and a +/−5% deviation threshold may be used on a second gas chemistry (e.g., CO₂). In addition, the baseline gas profile (e.g., the thresholds) may vary depending on the stages of the manufacturing process 102 as affected by the temperature, pressure, state of charge (SOC), or the like. Continuing with the above example, the first gas may be evaluated using a first threshold of +/−1% during the formation stage 104 while the same first gas may be evaluated using a second threshold of +/−2% at the degassing and sealing stage 106.

At operation 204, if the computing system 110 determines the concentration of any of the related gas chemistries is above the deviation threshold from the baseline profile, the process proceeds to operation 206 at which intervention operations are performed. The intervention operations may include identifying and removing the battery cells 120 from the manufacturing process 102 via the actuator 118 for further inspection. For instance, the gas analysis may be individually performed via the gas analyzer 122 for each individual cell 120 such that the subject cells may be easily identified.

If the answer for operation 204 is does not indicate a gas chemistry issue, the process proceeds to operation 208 to perform the thermal measurement evaluation by the thermal camera 124. In the present example, the thermal images of the battery cells 120 may be taken at the formation stage 104 and the aging stage 108 to measure the temperature of the battery cells 120. The measured cell temperature may be compared with one or more temperature thresholds indicated in the baseline profile to detect the presence of any overheating. The temperature threshold may be in the form of standard deviations. For instance, during the aging process of a specific type of battery cells 120, the external temperature of the battery cells 120 as measured by the thermal camera 124 should be around 50° C. for the baseline. If a large deviation (e.g., 3 sigma above the baseline) at a certain location of a battery cell 120 is detected indicative of a hotspot, the computing system 110 may flag the detected battery cells 120 and the process proceeds from operation 210 to operation 206 to perform the intervention operation and remove the corresponding cells 120.

Different temperature thresholds may be used at different locations of the cell 120. Taking the pouch lithium-ion battery cell for instance, it is common to detect different temperatures at various locations of the same cell 120. The temperature between the electrodes may be affected by the quality of the folded separator whereas the temperature in the middle of the cell may be affected by the internal insulation structure of the cell. Therefore, if the hotspot is detected around or between the electrodes, it may be more likely that the folded separator may be experiencing an issue. As an example, the temperature deviation threshold at the electrode region may be higher compared with the temperature deviation threshold at the body of the battery cells 120. The temperature deviation threshold may further vary depending on factors such as the SOC of the cells 120, type of cells (lithium-ion phosphate (LFP), nickel manganese cobalt (NMC)), ambient temperature, humidity, or the like.

Additionally or alternatively, a thermal map of the entire cell as compared to a baseline map may be utilized in addition to or in lieu of using the temperature at a specific location of the cell. A difference in temperature gradient in a cell may meet a prescribed criteria before a hot spot is detected. A temperature gradient across an entire cell may be used as early detection of a resulting hot spot.

At operation 212, the current measurement may be performed by the current sensor 126 at the aging stage 108. During the aging stage 108, the battery cells 120 may be subject to self-discharge which generates a small potentiostatic micro-current in units of micro-amps. The current sensor 126 may be continuously or periodically connected to the electrodes of the battery cells 120 to measure and compare the discharge current with a current deviation threshold. The current deviation threshold may be determined based on defined specifications of the battery cells 120. For example, if the cells 120 being manufactured are associated with a 180 mA potentiostatic discharge current which is deemed as within range, it is expected that all cells 120 of the current manufacturing process 102 would be around the 180 mA baseline current. If one or more cells are detected to discharge at +/−2% current deviation of the 180 mA baseline current, an issue may be determined and the process proceeds from operation 214 to operation 206 to perform the intervention operations.

At operation 216, the computing system 110 enhances the battery cells detecting process 200 using an artificial intelligence/machine learning framework. More specifically, the baseline profile (including various deviation thresholds) of the battery cells being manufactured may be adjusted using the framework based on the detection results of the process 200.

For example, if the current measurement at operation 212 consistently detects certain cells 120 that the gas analysis at operation 202 and thermal measurement at operation 208 both missed, the framework may be used to find patterns in the gas analysis and thermal measurement data and use those patterns to create better criteria to modify the baseline profile. The inconsistency may also be used as evidence for troubleshooters to look elsewhere in the process to find reasons for the issue.

Similarly, if the battery cells pass all the gas analysis at operation 202, the thermal measurement at operation 208, and the current measurement at operation 212, but have issues somewhere past the formation and aging stages, the data history for the cells may be analyzed to determine any patterns that could have alerted the computing system 110 sooner.

It is noted that although the process 200 is described above in a sequential manner, the present disclosure is not limited thereto and operations of the process 200 may be performed in different orders or simultaneously. For instance, the gas analysis (e.g., operations 202 and 204) and the thermal measurement (e.g., operations 208 and 210) may be performed simultaneously under essentially the same concept.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. The words used in the specification are words of description rather than limitation, and it is understood that various changes may be made without departing from the spirit and scope of the disclosure. The words processor and processors may be interchanged herein, as may the words controller and controllers.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A method comprising:
training a model implemented on a processor on formation cycling gas analyzer data of training battery cells, formation cycling infrared thermal imaging data of the training battery cells, and current leakage data of the training battery cells to generate a trained model such that the trained model during deployment with a line configured to manufacture production battery cells causes removal of certain of the production battery cells from the line responsive to measurements associated with the production battery cells on the line being identified by the trained model as corresponding to a predefined condition.

2. The method of claim 1, wherein the predefined condition is an impending self-discharge of the certain of the production battery cells.

3. The method of claim 1, wherein the predefined condition is an impending venting of gases from the certain of the production battery cells.

4. The method of claim 1, wherein the predefined condition is an impending thermal event of the certain of the production battery cells.

5. The method of claim 1, wherein the model is a machine learning model.

6. A battery manufacturing system comprising:
a trained model implemented on a processor of a manufacturing line that produces battery cells, and configured to cause removal of certain of the battery cells from the manufacturing line responsive to the trained model identifying the certain of the battery cells as being subject to a predefined condition based on measured data from the certain of the battery cells on the manufacturing line provided to the trained model.

7. The battery manufacturing system of claim 6, wherein the predefined condition is an impending self-discharge of the certain of the battery cells.

8. The battery manufacturing system of claim 6, wherein the predefined condition is an impending venting of gases from the certain of the battery cells.

9. The battery manufacturing system of claim 6, wherein the predefined condition is an impending thermal event of the certain of the battery cells.

10. The battery manufacturing system of claim 6, wherein the measured data is measured formation cycling gas data.

11. The battery manufacturing system of claim 6, wherein the measured data is measured formation cycling infrared thermal imaging data.

12. The battery manufacturing system of claim 6, wherein the measured data is measured current leakage data.

13. The battery manufacturing system of claim 6, wherein the model is a machine learning model.

14. A battery manufacturing system comprising:
a model implemented on a processor of a manufacturing line that produces production battery cells, and trained on formation cycling gas analyzer data of training battery cells so as to be configured to cause removal of certain of the production battery cells from the manufacturing line responsive to the model identifying the certain of the production battery cells as being subject to an impending venting of gases based on gas data measured during a formation cycling stage of the certain of the production battery cells.

15. The battery manufacturing system of claim 14, wherein the model is further trained on formation cycling infrared thermal imaging data of the training battery cells so as to be configured to cause removal of other of the production battery cells from the manufacturing line responsive to the model identifying the other of the production battery cells as being subject to an impending thermal event based on infrared thermal imaging data measured during the formation cycling stage of the other of the production battery cells.

16. The battery manufacturing system of claim 14, wherein the model is a machine learning model.
